(19) United States
(12) Patent Application Publication
(10) Pub. No.: US 2012/0171510 A1
(43) Pub. Date: Jul. 5, 2012

(54) CERAMIC PLATE WITH REFLECTIVE FILM AND METHOD OF MANUFACTURING THE SAME

(75) Inventors: Ta-Hsiang CHIANG, Taipei (TW); Chien-Cheng WEI, Taipei (TW)

(73) Assignee: TONG HSING ELECTRONIC INDUSTRIES, LTD., Taipei (TW)

(21) Appl. No.: 13/084,977

(22) Filed: Apr. 12, 2011

(30) Foreign Application Priority Data
Dec. 31, 2010 (TW) 099147066

(51) Int. Cl. B32B 15/04; C23C 14/18; C23C 14/34; C25D 5/54; B32B 17/06; B05D 3/02

(52) U.S. Cl. 428/623; 428/428; 427/379; 427/8; 204/192.1; 205/162; 428/433

(57) ABSTRACT

A ceramic plate with reflective film and method of manufacturing the same are provided. The ceramic plate with reflective film at least comprises a ceramic substrate and a reflective film. The reflective film at least includes a glass layer and a metal film with metal crystals. Each of the metal crystals possesses a particular diameter for providing high infrared reflectivity with a particular wavelength.

### CROSS-REFERENCE

This application claims the benefit of Taiwan application Serial No. 099147066, filed Dec. 31, 2010, the subject matter of which is incorporated herein by reference.

### BACKGROUND OF THE INVENTION

1. Field of the Invention

The present invention generally relates to a ceramic plate with reflective film, more particularly to a ceramic plate with high infrared reflectivity for improving the performance of fuel cells.

2. Description of the Prior Art

SOFC (Solid Oxide Fuel Cell) uses coal gas or natural gas as its fuel and solid non-porous metal oxide, such as immobilization zirconium oxide (ZrO₂), as its electrolyte. Electric power produces by ion transmitting from oxygen ions shuttling within crystals and the operation temperature reaches up to 800 to 1000 degree centigrade. SOFC (Solid Oxide Fuel Cell) provides high operation temperature and high electrode reacting rate for achieving high electric power generating efficiency without using precious metal as catalyst. Moreover, SOFC (Solid Oxide Fuel Cell) resets internal fuels by itself high temperature for simplifying the whole system. However, the material selection of electrode plates, bipolar plates and sealing materials are restricted by the high temperature operation.

U.S. Pat. No. 7,462,208 provides a planar micro fuel processor used in chemical reaction apparatus of fuel cells. The reaction cavity of the chemical reaction apparatus possesses a Dewar wall made from ceramic or metal. The Dewar wall further comprises a radiation preventing film. The radiation preventing film is a metal film, which is made of Au, Al or Ag, or a metal oxide film, which is made of Tin oxide (SnO₂), Indium oxide (In₂O₃) or Zinc oxide (ZNO). The radiation preventing film is used for reducing heat dissipating or heat radiating passing through the Dewar wall. However, the patent abovementioned neither discloses the relationship between the reflection range of infrared wavelength and associated reflection rate, nor the stability of the radiation preventing film in high temperature environment.

U.S. Pat. Application Publication No. 2008/0171245 discloses a heat radiation preventing film, reaction device, fuel cell device, electronic equipment, heat reflecting film and heat insulating container. The patent provides a reaction device used in fuel cells. The reaction device comprises a reaction device main body, an adhesion layer formed on a surface of the reaction device main body and a surface layer formed on a surface of the adhesion layer. The adhesion layer includes a material selected from the group consisting of tungsten (W) and molybdenum (Mo), and the surface layer includes Au. Although the patent aforementioned discloses that the surface layer includes a material selected from the group consisting of Au, Al, Ag, Cu or Ru, but Au and Ag are the better material choice due to Au and Ag possess higher reflection rate toward waves with wavelengths greater than 1 μm. However, the description of the patent application above further describes that the material of the surface layer of fuel cells' reaction main body has to be Au for restraining heat dissipating in 600 to 800 degree centigrade environment due to Ag in the surface layer will be vaporized at 600 degree centigrade. Therefore, heat radiation preventing film made of Ag is not suitable for use in fuel cells which are operated at high temperature.

U.S. Pat. Application Publication No. 2009/0246576 provides a reaction device an electronic equipment. The patent provides a reaction device used in fuel cells. The reaction device comprises a reaction device body and a container. A material of a reflective film disposed on inner surface of the container is selected from the group consisting of Au, Al, Ag, Cu and Ru. The reflective film made of Au, Al, Ag or Cu possesses infrared reflectivity higher than 90% with wavelengths greater than 1 μM. However, the patent aforementioned does not disclose the stability of the reflective film in high temperature environment.

Although the prior art disclosed different reflective films of fuel cells, there still exist many problems to increase the efficiency of fuel cells, e.g. the infrared reflectivity and stability. The infrared reflectivity will be improved by increase the reflect ability of the reflective film, in order to increase the reflect ability of the reflective film, needs to increase the metal crystal size because the larger metal crystal have greater reflectivity of the light, e.g. infrared reflectivity.

### SUMMARY OF THE INVENTION

According to the problems with the prior art, the present invention provides a ceramic plate with reflective film and method of manufacturing the same for improving the infrared reflection rate of the ceramic plate and improve the stability of the ceramic plate operating in high temperature environment by increasing sintering degree and times for controlling the diameter of metal crystals of the reflective film.

One method to manufacture a ceramic plate with reflective film that has the benefits previously described may include annealing and crystallization of the reflective film to achieve a predetermined metal crystal size (usually called “grain boundary,” “crystallite boundary,” “grain size,” or “crystallite size”) and decreasing the defects (e.g. hole, seam or chink) between metal crystals. Achieving the metal crystal size and decreasing the defects improve the infrared reflectivity of the ceramic plate.

An objective of the present invention is to provide a ceramic plate with reflective film.

Another objective of the present invention is to provide a ceramic plate with reflective film, wherein the reflective film at least comprises a glass layer and a metal film with metal crystals.

Another yet objective of the present invention is to provide a ceramic plate with reflective film, further comprising an Au film disposed on the surface of the reflective film.

Another yet objective of the present invention is to provide a ceramic plate with reflective film, wherein the metal film of the reflective film possesses metal crystals with a particular diameter.

Another yet objective of the present invention is to provide a ceramic plate with reflective film, wherein the ceramic plate is used for reflecting infrared with particular wavelengths.

Another yet objective of the present invention is to provide a ceramic plate with reflective film, wherein the ceramic plate possesses high infrared reflectivity with particular wavelengths.

Another yet objective of the present invention is to provide a ceramic plate with reflective film, wherein the ceramic plate possesses high stable temperature.

For achieving above objectives, the present invention is to provide a ceramic plate with reflective film, comprising: a ceramic substrate for constructing main body of the ceramic plate; a reflective film, including at least a glass layer and a metal film with metal crystals; wherein the glass layer is between the ceramic substrate and the metal film with metal crystals.

According to the ceramic plate with reflective film aforementioned, wherein the material of the ceramic substrate is aluminum oxide.

According to the ceramic plate with reflective film aforementioned, wherein the material of the metal film of the reflective film is selected from the group consisting of Au and Ag.

According to the ceramic plate with reflective film aforementioned, wherein the material of the glass layer of the reflective film is selected from the glass group consisting of PbO, SiO₂, CaO, Al₂O₃, Bi₂O₃, BaO, SrO, B₂O₃, MgO, ZrO, Fe₂O₃, MnO, CuO, CoO, Na₂O, P₂O₅, ZnO, GeO₂ and combination the same.

According to the ceramic plate with reflective film aforementioned, wherein the metal film of the reflective film possesses metal crystals with diameter range from 4μm to 15 μm.

According to the ceramic plate with reflective film aforementioned, wherein the ceramic plate is used for reflecting infrared with wavelengths greater than 1 μm.

According to the ceramic plate with reflective film aforementioned, wherein the infrared reflectivity of the ceramic plate at least 90%.

According to the ceramic plate with reflective film aforementioned, wherein the stable temperature is at least 600 degree centigrade.

According to the ceramic plate with reflective film aforementioned, further comprises an Au film formed on the metal film.

Another embodiment of the present invention is to provide a method of manufacturing a ceramic plate with reflective film, the method comprising following steps: (a) providing a ceramic substrate; (b) providing a reflective film material on the ceramic substrate; (c) pre-baking the ceramic substrate with the reflective film material with a pre-baking temperature; (d) sintering the ceramic substrate with the reflective film material with a sintering temperature; (e) annealing for forming a ceramic plate with reflective film.

According to the method of manufacturing a ceramic plate with reflective film aforementioned, further comprises a measuring and determining step (f) after step (e) for measuring the metal crystals diameters of the metal film of the reflective film; wherein if the metal crystals diameters of the metal film of the reflective film are out of a predetermined range, it repeats step (d), step (e) and step (f) till the metal crystals diameters of the metal film of the reflective film match the predetermined range.

According to the method of manufacturing a ceramic plate with reflective film aforementioned, further comprises an Au film formed on the metal film of the ceramic plate with reflective film.

According to the method of manufacturing a ceramic plate with reflective film aforementioned, wherein the Au film formed on the ceramic substrate by sputtering, electroplating, smearing or pasting.

According to the method of manufacturing a ceramic plate with reflective film aforementioned, wherein the pre-baking temperature is at least 100 degree centigrade.

According to the method of manufacturing a ceramic plate with reflective film aforementioned, wherein the pre-baking period is at least 10 minutes.

According to the method of manufacturing a ceramic plate with reflective film aforementioned, wherein the sintering temperature is at least 850 degree centigrade.

According to the method of manufacturing a ceramic plate with reflective film aforementioned, wherein the predetermined range of metal crystals diameters of the metal film of the reflective film is from 4μm to 15 μm.

According to the method of manufacturing a ceramic plate with reflective film aforementioned, wherein the ceramic plate is used for reflecting infrared with wavelengths greater than 1 μm.

According to the method of manufacturing a ceramic plate with reflective film aforementioned, wherein the infrared reflectivity of the ceramic plate at least 90%.

According to the method of manufacturing a ceramic plate with reflective film aforementioned, wherein the stable temperature is at least 600 degree centigrade.

According to the method of manufacturing a ceramic plate with reflective film aforementioned, further comprises an Au film formed on the metal film.

Another yet embodiment of the present invention is to provide a method of manufacturing a ceramic plate with reflective film, the method comprising following steps: (a) providing a ceramic substrate; (b) providing a reflective film material on the ceramic substrate; (c) pre-baking the ceramic substrate with the reflective film material with a pre-baking temperature; (d) sintering the ceramic substrate with the reflective film material with a gradient sintering temperature; (e) annealing for forming a ceramic plate with reflective film.

According to the method of manufacturing a ceramic plate with reflective film aforementioned, further comprises an Au film formed on the metal film of the ceramic plate with reflective film.

According to the method of manufacturing a ceramic plate with reflective film aforementioned, wherein the Au film is formed on the ceramic substrate by sputtering, electroplating, smearing or pasting.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits, and advantages of the preferred embodiments of the present invention will be readily understood by the accompanying drawings and detailed descriptions, wherein:

FIG. 1 illustrates a diagram of the ceramic plate with reflective film of the present invention.

FIG. 2 illustrates a flow chart of the method of manufacturing a ceramic plate with reflective film of the present invention.

FIG. 3 illustrates a curve diagram between sintering temperature and sintering temperature of the ceramic plate with reflective film of the present invention.

FIG. 4 illustrates a cross-section image under electron microscope (2000 times) of the ceramic plate with reflective film of the present invention.

FIG. 5(a) to FIG. 5(h) illustrate images under electron microscope (1800 times) of the ceramic plate with reflective film formed after sintering the ESL ceramic plate with different temperatures and times.

FIG. 6(a) to FIG. 6(l) illustrate images under electron microscope (1800 times) of the ceramic plate with reflective film formed after sintering the ESL, Heraeus and Ferro ceramic plates with different temperatures and times.

FIG. 7 illustrates another diagram of the ceramic plate with reflective film of the present invention.

### DETAILED DESCRIPTION OF THE INVENTION

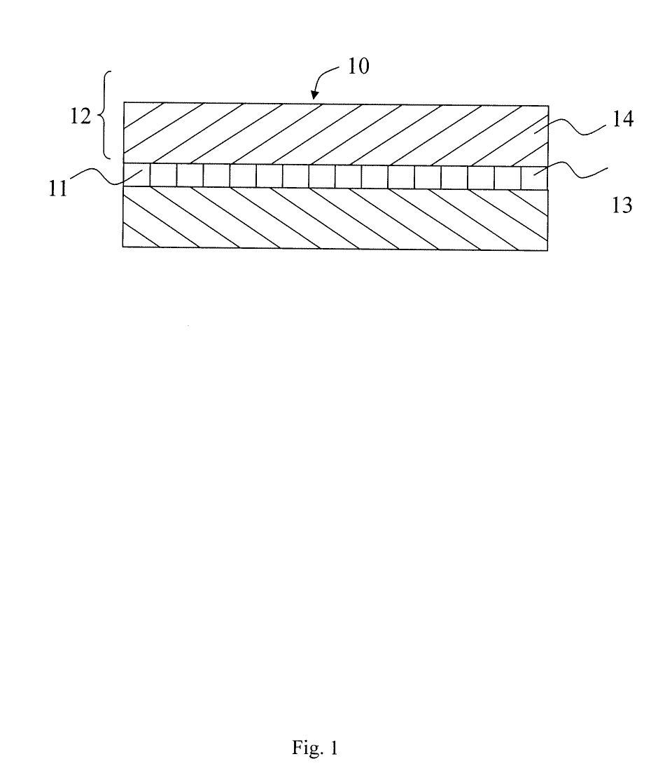

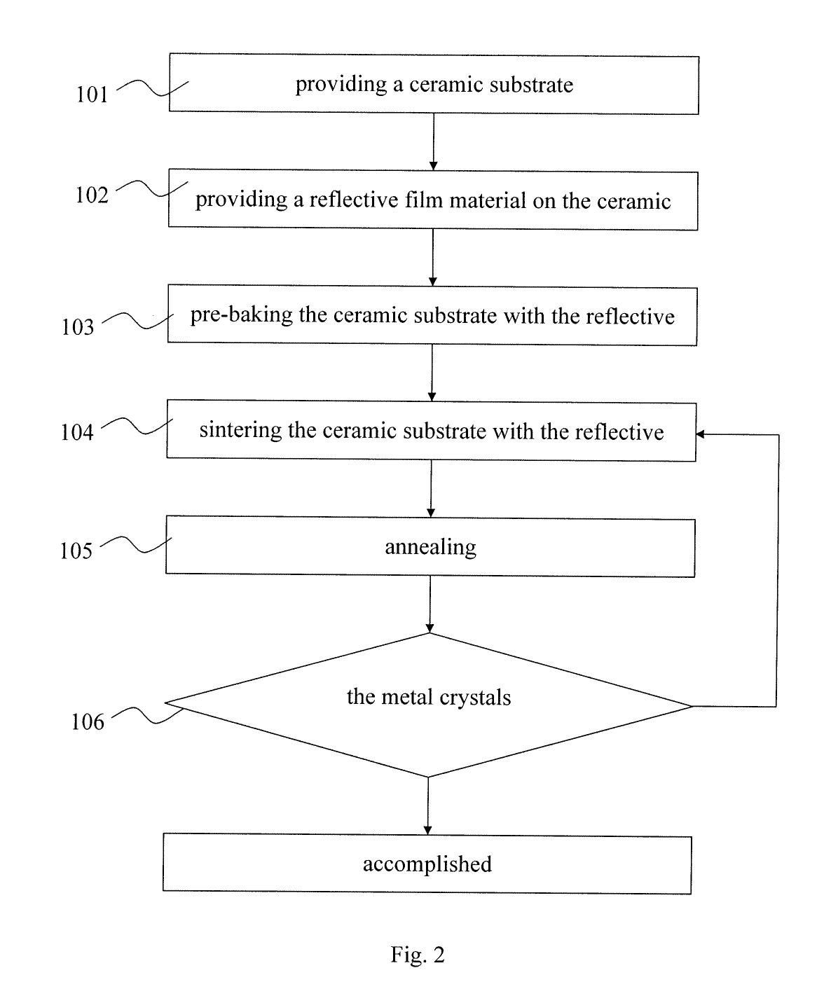

Referring to FIG. 1 and FIG. 2, FIG. 1 illustrates a diagram of the ceramic plate 10 with reflective film of the present invention and FIG. 2 illustrates a flow chart of the method of manufacturing a ceramic plate with reflective film of the present invention.

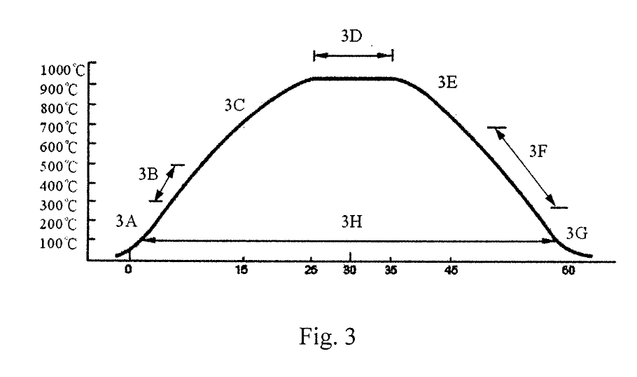

Referring to FIG. 2, an illustrative method to manufacture the ceramic plate may include the following steps. Providing a ceramic substrate 11 at the first step 101, and providing a reflective film material on the ceramic substrate 11 at the step 102, and then in pre-baking the step 103, the ceramic substrate 11 with the reflective film material is heated at 150 degree centigrade for 15 minutes in the heating chamber for pasting the reflective film material on the ceramic substrate 11 is smooth. After the step 103, at step 104, sintering the ceramic substrate 11 with the reflective film material. Annealing process step 105 comes after the sintering process step 104 for forming a ceramic plate with reflective film. The reflective film material becomes a reflective film 12 after the sintering process and reflective film 12 includes a glass layer 13 formed on a surface of the ceramic substrate 11 and metal film 14 with metal crystals formed on the glass layer 13. The sintering curve diagram of the sintering process step 104 and the annealing step 105 shown in FIG. 3. After the annealing process step 105, measures the metal crystals diameters of the metal film 14 at step 106. If the metal crystals diameters of the metal film 14 is not the predetermined range as 4 μm to 15 μm, repeat the sintering process step 104 and the annealing process step 105 till the metal crystals diameters of the metal film 14 reach the predetermined range and accomplish the ceramic plate of the present invention.

FIG. 3 illustrates a curve diagram between sintering temperature and sintering temperature of the ceramic plate with reflective film of the sintering process step 104 and the annealing step 105, the present invention. The sintering process takes 60 minutes at a time and is classed with 7 sections (3A to 3G) according sintering temperature and sintering period. In FIG. 3, section 3H takes 50 to 55 minutes with temperature greater than 100 degree centigrade. Each of the sections is described as follows.

After putting the ceramic plate with reflective film into the sintering cavity, raising the temperature in the sintering cavity rapidly from room temperature to 100 degree centigrade at section 3A, and kept heating to 300 degree centigrade. Section 3B, raising the sintering cavity temperature from 300 to 500 degree centigrade stably with the rate of 50 degree centigrade per minute. Section 3C follows section 3B, raising the sintering cavity temperature to 930 degree centigrade. Section 3D, maintain the temperature (930 degree centigrade) for 10 minutes at section 3D, the ceramic plate with reflective film sintering at a high temperature such as 930 degree centigrade. Section 3E represents the section for annealing. After the 10 minutes annealing process, the temperature in the sintering cavity decrease to 700 degree centigrade. Section 3F follows section 3E for decreasing the temperature in the sintering cavity rapidly to 300 degree centigrade with the rate of 50 degree centigrade per minute. After the temperature in the sintering cavity decreased slowly to room temperature at section 3G, the sintering process is accomplished after the ceramic plate ejected from the sintering cavity.

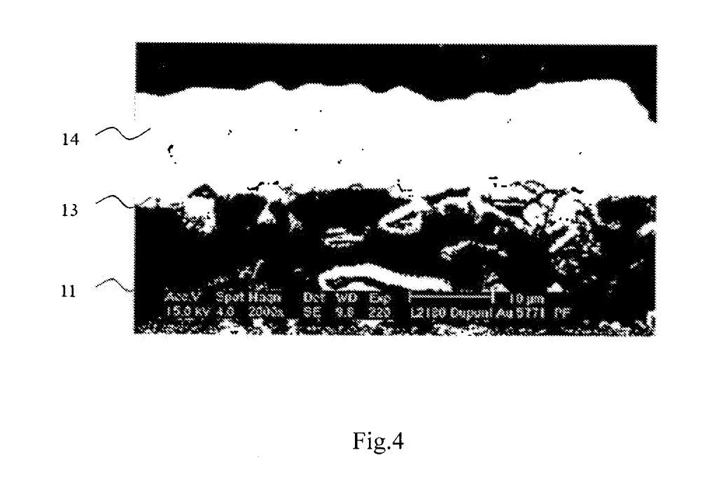

FIG. 4 illustrates a cross-section image under electron microscope (2000 times) of the ceramic plate with reflective film of the present invention. The ceramic plate 10 presents three-layer architecture certainly as shown in FIG. 1 after accomplishing the sintering process of the present invention. The three-layer architecture from down to up in turn are ceramic substrate 11, glass layer 13 and metal film 14. There are pluralities of defects (eg. hole, seam, or chink) inside the ceramic substrate 11, residual pieces remained on the surface of the ceramic substrate 11, and recesses and projections on the surface of the ceramic substrate 11. The glass layer 13 is formed on the ceramic substrate 11 and the metal film 14 possessed pits inside and a plurality of recesses and projections on its surface is formed on the glass layer 13. The glass layer 13 fills the recesses and projections on the surface of the ceramic substrate 11 for combining tightly to each other.

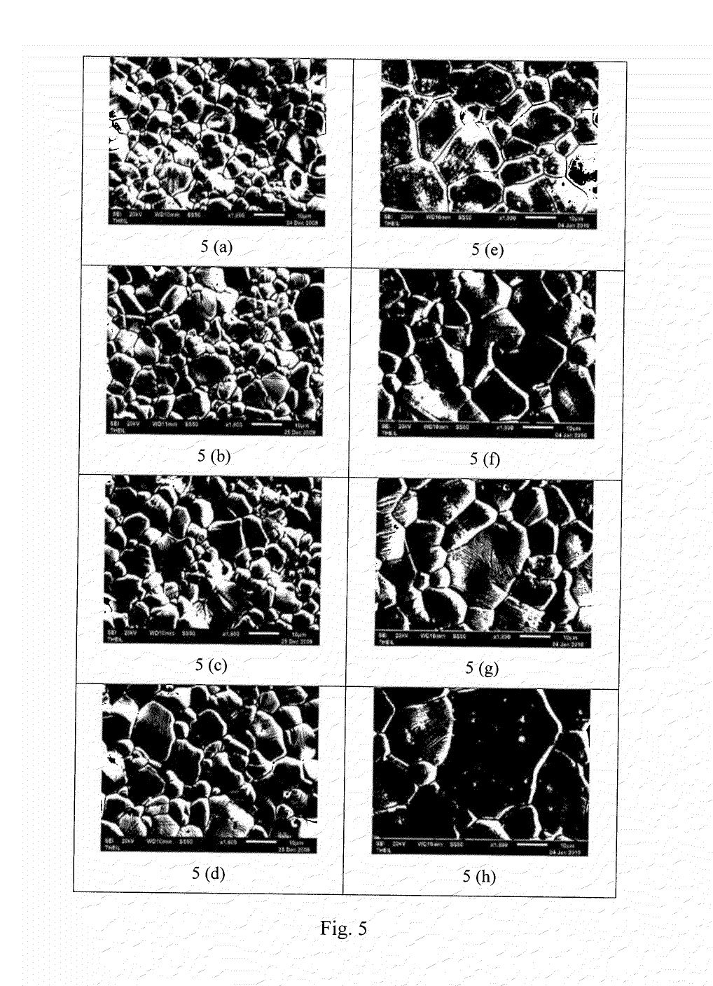

FIG. 5(a) to FIG. 5(h) illustrate images under electron microscope (1800 times) of the ceramic plate with reflective film formed after sintering the ESL (an electroplating technology) ceramic plate with different temperatures and times. The ESL ceramic plate is provide an ESL reflective film material (Electro-Science Laboratories, Inc. product No. 9912K) on the ceramic substrate, then pre-baking the ceramic substrate with the reflective film material with 150 degree centigrade for 15 minutes as the step 103, sintering the ceramic substrate with the reflective film material with 850 degree centigrade for 60 minutes as the step 104, and annealing after the sintering process for acquiring a ceramic plate with reflective film as the step 105, the metal crystal diameters of the metal film on the surface of the ceramic substrate become larger and larger as shown in FIG. 5(a) to FIG. 5(d).

As shown in FIG. 5(a) and Table 1, the metal crystals diameters of the reflective film surface with average diameter of 4.2 μm possess extremely different sizes to each other. It means that there are pluralities of defects existing and the surface of the reflective film is still roughly after operating the sintering process once. For improving the infrared reflectivity of the ceramic plate, the metal crystal size of the reflective film must be increased. Therefore, the ceramic plate is sintered with 850 degree centigrade for 60 minutes and annealed again after the first sintering process. At this time, as shown in FIG. 5(b), the metal crystals diameters of the reflective film surface with average diameter of 4.6 μm (see Table 1, sintering at 850 degree centigrade for 2 times) is larger than FIG. 5(b)'s and the number of defects are decreased obviously. The metal crystal diameter and metal crystal size of the reflective film is increased after the second sintering process. The result of the third sintering process and fourth sintering process are shown in FIG. 5(c) and FIG. 5(d), respectively.

From the description above, the metal crystals size of the reflective film surface are getting larger following the times of the sintering process increase. As shown in FIG. 5(c), 5(d) and Table 1, the average diameters of the metal crystals is 5.0 μm after repeating the sintering process 104 and the annealing process step 105 for three times, and the average diameters of the metal crystals is 6.0 μm after repeating the sintering process 104 and the annealing process step 105 for three times.

If the sintering temperature from the 850 degree centigrade raise to 930 degree centigrade, the sintering result of the metal crystals diameters of the reflective film surface of the ceramic plate are shown in FIG. 5(e) to FIG. 5(h), respectively. As the results shown in FIG. 5(e) and Table 1, sintering the ceramic plate with reflective film one times with 930 degree centigrade, the metal crystals diameters of the reflective film of the ceramic plate surface become 11 μm. The result shows that the ceramic plate with reflective film sintering at high temperature, the metal crystals diameter is larger than the sintering with low temperature.

The results after the second, third and fourth sintering process with the sintering temperature of 930 degrees centigrade are shown in FIG. 5(f), FIG. 5(g) and FIG. 5(h), respectively. The metal crystals diameters of the reflective film surface are getting larger following the times of the sintering process and the defects between the metal crystals are decreasing following the times of the sintering process. As shown in FIG. 5(h), the metal crystals diameters of the reflective film of the ceramic plate surface are increased to 13.3 μm after the fourth sintering process with 930 degree centigrade and defects between the metal crystals are almost disappeared. The metal crystal size of the reflective film is substantially increased. Thus, rising the sintering temperature or times of sintering process are both increasing the metal crystals' diameters effectively, and the metal crystal size of the reflective film of the ceramic plate surface and the infrared reflectivity is consequently improved.

TABLE 1

| | Metal crystals diameters | Metal crystals diameters |
|---|---|---|
| Sintering | (sintering at 850 degree | (sintering at 930 degree |
| times | centigrade) | centigrade) |
| 1 times | 4.2 μm | 11.0 μm |
| 2 times | 4.6 μm | 11.2 μm |
| 3 times | 5.0 μm | 11.4 μm |
| 4 times | 6.0 μm | 13.3 μm |

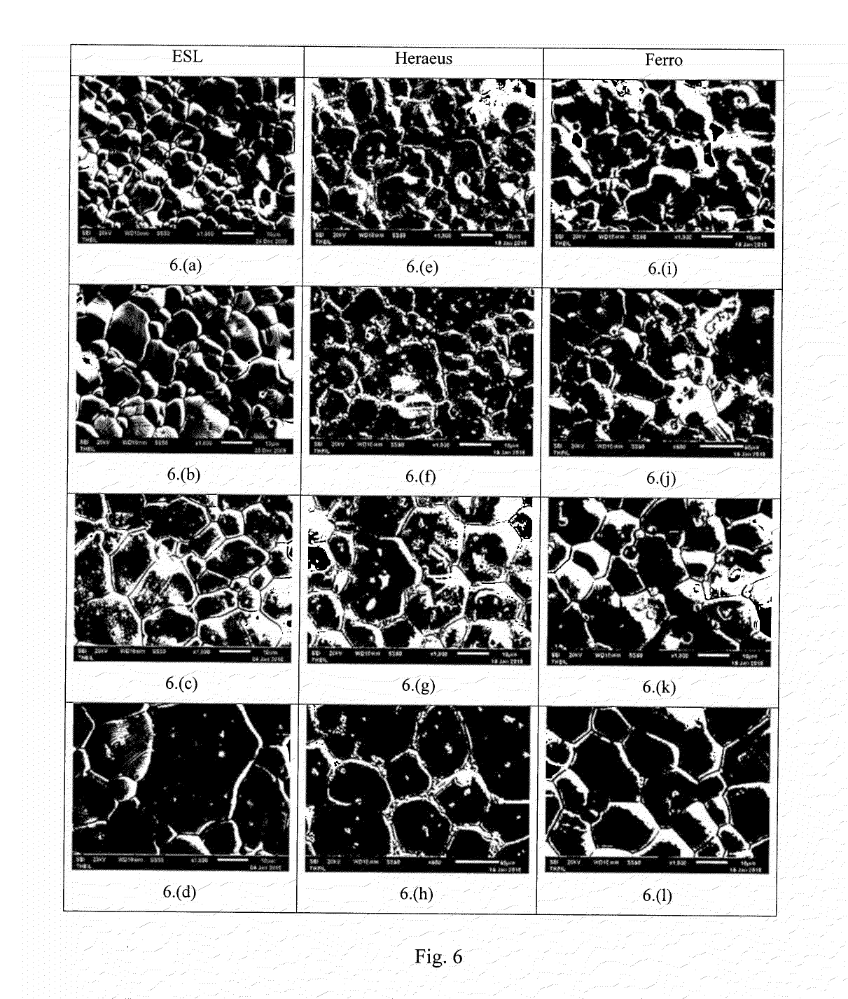

FIG. 6(a) to FIG. 6(l) illustrate images under electron microscope (1800 times) of the ceramic plate with reflective film formed after sintering the ESL, Heraeus and Ferro ceramic plates with different temperatures and times. After pre-baking the ceramic substrate with the reflective film material with 125 degree centigrade for 15 minutes, sintering the ceramic substrate with the reflective film material with the predetermined temperature for 60 minutes, and annealing after the sintering process for acquiring a ceramic plate with reflective film, the ceramic plate with reflective film is acquired.

The images of the ESL ceramic plate with reflective film after sintering one time with 850 degree centigrade, sintering four times with 850 degree centigrade, sintering one time with 930 degree centigrade and sintering four times with 930 degree centigrade are shown in FIG. 6(a), FIG. 6(b), FIG. 6(c) and FIG. 6(d), respectively. The images of the Ferro ceramic plate with reflective film after sintering one time with 850 degree centigrade, sintering four times with 850 degree centigrade, sintering one time with 930 degree centigrade and sintering four times with 930 degree centigrade are shown in FIG. 6(i), FIG. 6(j), FIG. 6(k) and FIG. 6(l), respectively.

As the results shown in FIG. 6(a) to FIG. 6(l) and Table 2, we can acquire that rising the sintering temperature or times of sintering process are both increasing the metal crystals' diameters effectively. Meanwhile, the defects, such as defects or residual pieces are decreased and the smooth level of the reflective film of the ceramic plate surface is consequently improved.

Table 3 and Table 4 represent the 2 to 12 μm infrared reflectivity of the ceramic plate of the Heraeus ceramic plate and Ferro ceramic plate with reflective film. The Heraeus ceramic plate is provide an Heraeus reflective film (Heraeus Ag conductor product No. C8729) on the ceramic substrate and the Ferro ceramic plate is provide an Ferro reflective film material (Ferro Ag conductor product No. C3059) on the ceramic substrate. After sintering the Heraeus ceramic plate and the Ferro ceramic plate with different temperatures and times as shown in FIG. 6(e) to FIG. 6(h) and FIG. 6(i) to FIG. 6(l). As shown, the maximum infrared reflectivity of the Heraeus ceramic plate with reflective film is greater than 99% and the minimum infrared reflectivity of the Heraeus ceramic plate with reflective film is increased from 93.52% to 94% or above; the maximum infrared reflectivity of the Ferro ceramic plate with reflective film is increased from 97.30% to 99.35% and the minimum infrared reflectivity of the Ferro ceramic plate with reflective film is substantially increased from 90.84% to 96.19% or above. This result shows that increases the sintering temperature or sintering times of sintering process are both improving the infrared reflectivity of the ceramic plate with reflective film, therefore the efficiency of fuel cells will be increased.

TABLE 2
metal crystals diameters

| | substrate | | |
|---|---|---|---|
| | Metal crystals | Metal crystals | Metal crystals |
| | diameters of | diameters of | diameters of |
| | the ESL | the Heraeus | the Ferro |
| sintering | ceramic | ceramic | ceramic |
| temperature and | plate with | plate with | plate with |
| sintering times | reflective film | reflective film | reflective film |
| 850° C., 1 times | 4.2 μm | 5.2 μm | 5.8 μm |
| 850° C., 4 times | 6.0 μm | 8.3 μm | 9.3 μm |
| 930° C., 1 times | 11.0 μm | 9.7 μm | 11.7 μm |
| 930° C., 4 times | 13.3 μm | 14 μm | 13.1 μm |

TABLE 3
infrared reflectivity (ESL ceramic plate with reflective film)

sintering temperature and sintering times

| Infrared | 850° C. | 850° C. | 930° C. | 930° C. |
|---|---|---|---|---|
| reflectivity | 1x | 4x | 1x | 4x |
| MAX Infrared | 99.711 | 99.7329 | 99.4793 | 99.6787 |
| reflectivity | | | | |
| MIN. Infrared | 93.5206 | 94.5929 | 94.8589 | 94.3883 |
| reflectivity | | | | |

TABLE 4
infrared reflectivity (Ferro ceramic plate with reflective film)

sintering temperature and sintering times

| Infrared | 850° C. | 850° C. | 930° C. | 930° C. |
|---|---|---|---|---|
| reflectivity | 1x | 4x | 1x | 4x |
| MAX Infrared | 97.3081 | 98.2648 | 99.3118 | 99.3588 |
| reflectivity | | | | |
| MIN. Infrared | 90.8486 | 92.5437 | 94.2411 | 96.1942 |
| reflectivity | | | | |

According to the description of tables 2-4 raising the sintering temperature and sintering times of sintering process can increase the diameter of the metal crystals of the ceramic plate, and the infrared reflectivity increases with the increase in diameter of the metal crystals of the ceramic plate.

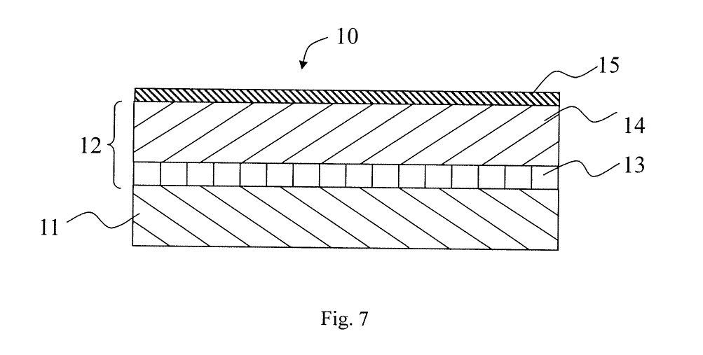

FIG. 7 illustrates another diagram of the ceramic plate with reflective film of the present invention. Method of manufacturing the ceramic plate 10 with reflective film is through following steps. The method provides a ceramic substrate 11 at first, and provides a reflective film material on the ceramic substrate 11, and then pre-baking the ceramic substrate 11 with the reflective film material with 125 degree centigrade. After that, sinters the ceramic substrate 11 with the reflective film material with 930 degree centigrade. Annealing process comes after the sintering process for forming the ceramic plate 10 with reflective film. At this time, metal crystals sizes are measured by electron microscope. Then an Au film is formed on the reflective film 12 by sputtering. The ceramic substrate 11 is treated as a main body of the ceramic plate 10 with reflective film. After the sintering process, the reflective film 12 becomes a glass layer 13 formed on a surface of the ceramic substrate 11 and metal film 14 with metal crystals formed on the glass layer 13.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A ceramic plate with reflective film, comprising:
a ceramic substrate to form the main body of the substrate;
a reflective film, including at least a glass layer and a metal film with metal crystals;
wherein the glass layer is formed on a surface of the ceramic substrate and the metal film with metal crystals is formed on the glass layer.

2. The ceramic plate with reflective film according to claim 1, further comprises an Au film formed on the metal film.

3. The ceramic plate with reflective film according to claim 1, wherein the metal film is selected from the group consisting of Au and Ag.

4. The ceramic plate with reflective film according to claim 1, wherein the metal film possesses metal crystals with diameter range from 4 μM to 15 μm.

5. The ceramic plate with reflective film according to claim 1, wherein the glass layer is selected from the glass group consisting of PbO, SiO₂, CaO, Al₂O₃, Bi₂O₃, BaO, SrO, B₂O₃, MgO, ZrO, Fe₂O₃, MnO, CuO, CoO, Na₂O, P₂O₅, ZnO, GeO₂ and combination the same.

6. The ceramic plate with reflective film according to claim 1, wherein the ceramic plate is used for reflecting infrared with wavelengths greater than 1 μm.

7. The ceramic plate with reflective film according to claim 6, wherein the ceramic plate is used for reflecting infrared with wavelengths from 2 μm to 12 μm.

8. The ceramic plate with reflective film according to claim 1, wherein the ceramic plate of the infrared reflectivity of at least 90%.

9. The ceramic plate with reflective film according to claim 8, wherein the ceramic plate of the infrared reflectivity of at least 95%.

10. The ceramic plate with reflective film according to claim 9, wherein the ceramic plate of the infrared reflectivity of at least 97%.

11. The ceramic plate with reflective film according to claim 10, wherein the ceramic plate of the infrared reflectivity of at least 99%.

12. The ceramic plate with reflective film according to claim 1, wherein the ceramic plate possesses high stable temperature, the stable temperature of the ceramic plate is at least 600 degree centigrade.

13. The ceramic plate with reflective film according to claim 12, wherein the stable temperature of the ceramic plate is at least 700 degree centigrade.

14. The ceramic plate with reflective film according to claim 13, wherein the stable temperature of the ceramic plate is at least 800 degree centigrade.

15. The ceramic plate with reflective film according to claim 14, wherein the stable temperature of the ceramic plate is at least 900 degree centigrade.

16. A method of manufacturing a ceramic plate with reflective film, the method comprising following steps:
(a) providing a ceramic substrate;
(b) providing a reflective film material on the ceramic substrate;
(c) pre-baking the ceramic substrate with the reflective film material with a pre-baking temperature;
(d) sintering the ceramic substrate with the reflective film material with a sintering temperature; and
(e) annealing for forming a ceramic plate with reflective film.

17. The method of manufacturing a ceramic plate with reflective film according to claim 16, further comprises a measuring and determining step (f) after step (e) for measuring the metal crystals diameters of the metal film of the reflective film; wherein if the metal crystals diameters of the metal film of the reflective film are out of a predetermined range, the steps of step (d), step (e) and step (f) are repeated till the metal crystals diameters of the metal film of the reflective film match the predetermined range.

18. The method of manufacturing a ceramic plate with reflective film according to claim 17, further comprises an Au film formed on the metal film.

19. The method of manufacturing a ceramic plate with reflective film according to claim 18, wherein the Au film is formed on the ceramic substrate by sputtering, electroplating, smearing or pasting.

20. The method of manufacturing a ceramic plate with reflective film according to claim 16, wherein pre-baking temperature is at least 100 degree centigrade.

21. The method of manufacturing a ceramic plate with reflective film according to claim 20, wherein the pre-baking temperature is from 110 to 200 degree centigrade.

22. The method of manufacturing a ceramic plate with reflective film according to claim 16, wherein the pre-baking period of the step (c) is at least 10 minutes.

23. The method of manufacturing a ceramic plate with reflective film according to claim 22, wherein the pre-baking period is 15 to 20 minutes.

24. The method of manufacturing a ceramic plate with reflective film according to claim 16, wherein the sintering temperature is at least 850 degree centigrade.

25. The method of manufacturing a ceramic plate with reflective film according to claim 24, wherein the sintering temperature is at least 900 degree centigrade.

26. The method of manufacturing a ceramic plate with reflective film according to claim 25, wherein the sintering temperature is at least 930 degree centigrade.

27. The method of manufacturing a ceramic plate with reflective film according to claim 26, wherein the sintering temperature is at least 950 degree centigrade.

28. The method of manufacturing a ceramic plate with reflective film according to claim 16, wherein the metal film possesses metal crystals with diameter range from 4 μm to 15 μm.

29. A method of manufacturing a ceramic plate with reflective film, the method comprising following steps:
(a) providing a ceramic substrate;
(b) providing a reflective film material on the ceramic substrate;
(c) pre-baking the ceramic substrate with the reflective film material with a pre-baking temperature;
(d) sintering the ceramic substrate with the reflective film material with a gradient sintering temperature; and
(e) annealing for forming a ceramic plate with reflective film.

30. The method of manufacturing a ceramic plate with reflective film according to claim 29, further comprises an Au film formed on the metal film.

31. The method of manufacturing a ceramic plate with reflective film according to claim 30, wherein the Au film is formed on the ceramic substrate by sputtering, electroplating, smearing or pasting.
